(19) United States
(12) Patent Application Publication
(10) Pub. No.: US 2024/0051067 A1
(43) Pub. Date: Feb. 15, 2024

(54) LASER PROCESSING DEVICE AND LASER PROCESSING METHOD

(71) Applicant: HAMAMATSU PHOTONICS K.K., Hamamatsu-shi, Shizuoka (JP)

(72) Inventors: Yo SUGIMOTO, Hamamatsu-shi, Shizuoka (JP); Takeshi SAKAMOTO, Hamamatsu-shi, Shizuoka (JP); Takafumi OGIWARA, Hamamatsu-shi, Shizuoka (JP); Naoki UCHIYAMA, Hamamatsu-shi, Shizuoka (JP); Takashi KURITA, Hamamatsu-shi, Shizuoka (JP); Ryo YOSHIMURA, Hamamatsu-shi, Shizuoka (JP)

(73) Assignee: HAMAMATSU PHOTONICS K.K., Hamamatsu-shi, Shizuoka (JP)

(21) Appl. No.: 18/266,842

(22) PCT Filed: Dec. 20, 2021
(86) PCT No.: PCT/JP2021/047081

§ 371 Date: Jun. 13, 2023

(30) Foreign Application Priority Data
Dec. 25, 2020 (JP) 2020-217212

(51) Int. Cl. B23K 26/351; B23K 26/064; B23K 26/04

(52) U.S. Cl. CPC B23K 26/351; B23K 26/064; B23K 26/048

(57) ABSTRACT

A laser processing method includes: a first step of preparing a wafer including a plurality of functional elements disposed to be adjacent to each other via a street; and a second step of, after the first step, irradiating the street with laser light based on information regarding the street such that a surface layer of the street is removed in a first region of the street and the surface layer remains in a second region of the street. The information regarding the street includes information indicating that, when a modified region is formed in the wafer along a line passing through the street, a fracture extending from the modified region does not reach the street along the line in the first region, and reaches the street along the line in the second region.

### TECHNICAL FIELD

The present disclosure relates to a laser processing apparatus and a laser processing method.

### BACKGROUND ART

In a wafer including a plurality of functional elements disposed to be adjacent to each other via streets, an insulating film (Low-k film or the like) and a metal structure (metal piles, metal pads, and the like) may be formed on the surface layer of the street. In such a case, if a modified region is formed in the wafer along a line passing through the street, and the wafer is chipped for each functional element by extending a fracture from the modified region, the quality of the chip may be deteriorated, for example, film peeling may occur in the portion along the street. Therefore, when the wafer is chipped for each functional element, grooving processing of removing the surface layer of the street by irradiating the street with laser light may be performed (see Patent Literatures 1 and 2, for example).

### CITATION LIST

### Patent Literature

Patent Literature 1: Japanese Unexamined Patent Publication No. 2007-173475
Patent Literature 2: Japanese Unexamined Patent Publication No. 2017-011040

### SUMMARY OF INVENTION

### Technical Problem

However, when the street is irradiated with laser light under a condition that the metal structure may be reliably removed, thermal damage may occur in a portion at which the metal structure is not formed in the surface layer of the street. Such thermal damage causes deterioration of the quality of the chip. On the other hand, when the street is irradiated with the laser light under the condition that the thermal damage may be reliably suppressed, a portion of the metal structure may remain. Such remaining of the metal structure causes inhibition of complete chipping of the wafer.

Therefore, an object of the present disclosure is to provide a laser processing apparatus and a laser processing method capable of reliably chipping a wafer for each functional element and suppressing deterioration in chip quality.

### Solution to Problem

According to an aspect of the present disclosure, a laser processing apparatus includes a support part configured to support a wafer including a plurality of functional elements disposed to be adjacent to each other via a street, an irradiation part configured to irradiate the street with laser light, and a control part configured to control the irradiation part based on information regarding the street such that a surface layer of the street is removed in a first region of the street and the surface layer remains in a second region of the street. The information regarding the street includes information indicating that, when a modified region is formed in the wafer along a line passing through the street, a fracture extending from the modified region does not reach the street along the line in the first region, and reaches the street along the line in the second region.

In the laser processing apparatus, the surface layer of the street is removed in the first region having an assumption “that, when the modified region is formed in the wafer along the line passing through the street, the fracture extending from the modified region does not reach the street along the line”. In addition, the surface layer of the street is not removed in the second region having an assumption “that, when the modified region is formed in the wafer along the line passing through the street, the fracture extending from the modified region reaches the street along the line”. Thus, when the wafer is chipped for each functional element, it is possible to cause the fracture extending from the modified region to reach the street along the line in the first region and the second region. In addition, it is possible to prevent an occurrence of thermal damage at least in a portion corresponding to the second region. Therefore, the laser processing apparatus makes it possible to reliably chip a wafer for each functional element and to suppress deterioration in chip quality.

In the laser processing apparatus according to the aspect of the present disclosure, the control part may control at least one of the support part and the irradiation part such that the laser light relatively moves along the street, and the control part may control the irradiation part such that an output of the laser light is turned ON when the laser light relatively moves on the first region, and the output of the laser light is turned OFF when the laser light relatively moves on the second region. According to this configuration, it is possible to reliably remove the surface layer of the street in the first region, and to reliably leave the surface layer of the street in the second region.

The laser processing apparatus according to the aspect of the present disclosure may further include an image capturing part configured to acquire image data of the street. The control part may control the irradiation part based on the image data and the information regarding the street such that the surface layer is removed in the first region and the surface layer remains in the second region. According to this configuration, it is possible to reliably perform the irradiation with the laser light in which the surface layer of the street is removed in the first region and the surface layer of the street is left in the second region.

The laser processing apparatus according to the aspect of the present disclosure may further include a distance measuring part configured to acquire height data of the street. The control part may control the irradiation part based on the height data and the information regarding the street such that the surface layer is removed in the first region and the surface layer remains in the second region. According to this configuration, it is possible to reliably perform the irradiation with the laser light in which the surface layer of the street is removed in the first region and the surface layer of the street is left in the second region.

In the laser processing apparatus according to the aspect of the present disclosure, the information regarding the street may include position information of a tip of a fracture that does not reach the first region. According to this configuration, it is possible to irradiate the first region with laser light so that the fracture extending from the modified region reliably reaches the street along the line in the first region in which the surface layer of the street is removed.

According to another aspect of the present disclosure, a laser processing method includes a first step of preparing a wafer including a plurality of functional elements disposed to be adjacent to each other via a street, and a second step of, after the first step, irradiating the street with laser light based on information regarding the street such that a surface layer of the street is removed in a first region of the street and the surface layer remains in a second region of the street. The information regarding the street includes information indicating that, when a modified region is formed in the wafer along a line passing through the street, a fracture extending from the modified region does not reach the street along the line in the first region, and reaches the street along the line in the second region.

In the laser processing method, the surface layer of the street is removed in the first region having an assumption “that, when the modified region is formed in the wafer along the line passing through the street, the fracture extending from the modified region does not reach the street along the line”. In addition, the surface layer of the street is not removed in the second region having an assumption “that, when the modified region is formed in the wafer along the line passing through the street, the fracture extending from the modified region reaches the street along the line”. Thus, when the wafer is chipped for each functional element, it is possible to cause the fracture extending from the modified region to reach the street along the line in the first region and the second region. In addition, it is possible to prevent an occurrence of thermal damage at least in a portion corresponding to the second region. Therefore, the laser processing method makes it possible to reliably chip a wafer for each functional element and to suppress deterioration in chip quality.

The laser processing method according to the aspect of the present disclosure may further include a third step of acquiring information regarding the street by using a test wafer, before the first step. According to this configuration, it is possible to easily and accurately acquire the information regarding the street.

The laser processing method according to the aspect of the present disclosure may further include a fourth step of forming a modified region in the wafer along the line, after the first step. According to this configuration, it is possible to chip the wafer for each functional element by causing the fracture extending from the modified region to reach the street along the line.

### Advantageous Effects of Invention

According to the present disclosure, it is possible to provide a laser processing apparatus and a laser processing method capable of reliably chipping a wafer for each functional element and suppressing deterioration in chip quality.

### BRIEF DESCRIPTION OF DRAWINGS

FIG. 1 is a configuration diagram illustrating a laser processing apparatus according to an embodiment.

FIG. 2 is a plan view illustrating a wafer to be processed by the laser processing apparatus illustrated in FIG. 1.

FIG. 3 is a cross-sectional view illustrating a portion of the wafer illustrated in FIG. 2.

FIG. 4 is a plan view illustrating a portion of a street illustrated in FIG. 2.

FIG. 5 is a plan view illustrating a portion of a street for explaining grooving processing.

FIG. 6 is a flowchart illustrating a laser processing method according to the embodiment.

FIG. 7 is a cross-sectional view illustrating a portion of a wafer for explaining the laser processing method in the embodiment.

FIG. 8 is a plan view illustrating a portion of a street for explaining the laser processing method in the embodiment.

FIG. 9 is a cross-sectional view illustrating a portion of the wafer for explaining the laser processing method in the embodiment.

FIG. 10 is a cross-sectional view illustrating a portion of the wafer for explaining the laser processing method in the embodiment.

FIG. 11 is a plan view illustrating a portion of a street for explaining a laser processing method according to a modification example.

FIG. 12 is a plan view illustrating the portion of the street for explaining the laser processing method in the modification example.

FIG. 13 is a cross-sectional view illustrating a portion of the street for explaining the laser processing method in the modification example.

FIG. 14 is a configuration diagram illustrating a laser processing apparatus according to the modification example.

FIG. 15 is a flowchart illustrating the laser processing method in the modification example.

FIG. 16 is a plan view illustrating a portion of the street for explaining the laser processing method in the modification example.

### DESCRIPTION OF EMBODIMENTS

Hereinafter, embodiments of the present disclosure will be described in detail with reference to the drawings. The same or corresponding parts in the respective drawings are denoted with the same reference signs, and repetitive descriptions will be omitted.

[Configuration of Laser Processing Device]

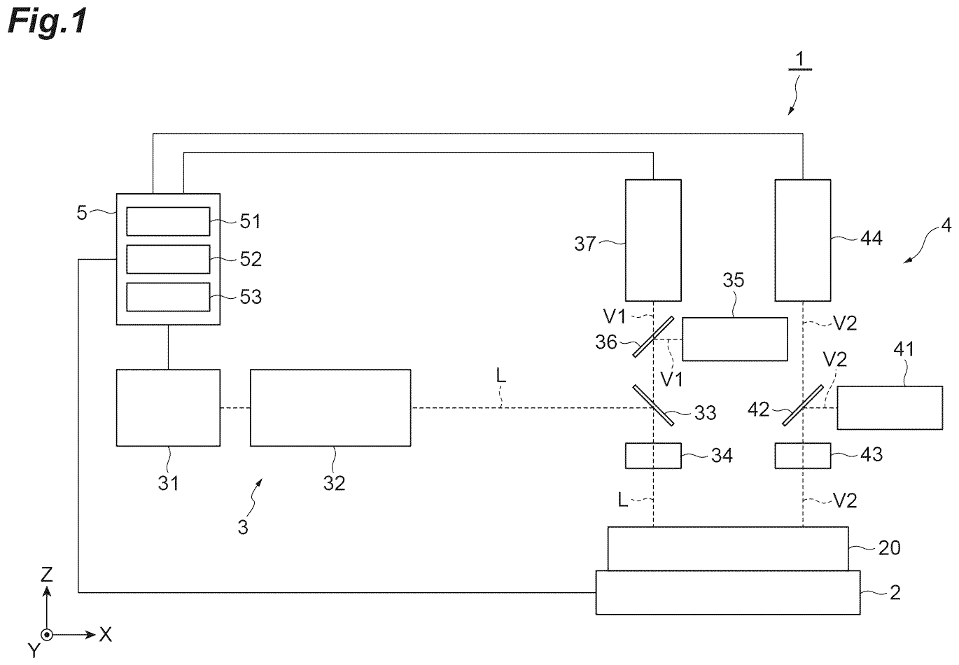

As illustrated in FIG. 1, a laser processing apparatus 1 includes a support part 2, an irradiation part 3, an image capturing part 4, and a control part 5. The laser processing apparatus 1 is a device that performs grooving processing of removing a surface layer of a street of a wafer 20 by irradiating the street (details will be described later) of the wafer 20 with laser light L. In the following description, three directions perpendicular to each other are referred to as an X direction, a Y direction, and a Z direction, respectively. As an example, the X direction is a first horizontal direction, the Y direction is a second horizontal direction perpendicular to the first horizontal direction, and the Z direction is a vertical direction.

The support part 2 supports the wafer 20. The support part 2 holds the wafer 20, for example, by attracting a film (not illustrated) attached to the wafer 20 such that the surface of the wafer 20 including a street faces the irradiation part 3 and the image capturing part 4. As an example, the support part 2 can move along the X-direction and the Y-direction, respectively, and can rotate around an axis parallel to the Z-direction as a center line.

The irradiation part 3 irradiates the street of the wafer 20 supported by the support part 2 with the laser light L. The irradiation part 3 includes a light source 31, a shaping optical system 32, a dichroic mirror 33, and a converging part 34. The light source 31 emits laser light L. The shaping optical system 32 adjusts the laser light L emitted from the light source 31. As an example, the shaping optical system 32 includes at least one of an attenuator that adjusts the output of the laser light L, a beam expander that expands the diameter of the laser light L, and a spatial light modulator that modulates the phase of the laser light L. When the shaping optical system 32 includes the spatial light modulator, the shaping optical system may include an imaging optical system constituting a double-sided telecentric optical system in which the modulation surface of the spatial light modulator and the incident pupil surface of the converging part 34 have an imaging relationship. The dichroic mirror 33 reflects the laser light L emitted from the shaping optical system 32 and enters the laser light L into the converging part 34. The converging part 34 converges the laser light L reflected by the dichroic mirror 33 on the street of the wafer 20 supported by the support part 2.

The irradiation part 3 further includes a light source 35, a half mirror 36, and an imaging element 37. The light source 35 emits visible light V1. The half mirror 36 reflects the visible light V1 emitted from the light source 35 and enters the visible light V1 into the converging part 34. The dichroic mirror 33 transmits the visible light V1 between the half mirror 36 and the converging part 34. The converging part 34 converges the visible light V1 reflected by the half mirror 36 on the street of the wafer 20 supported by the support part 2. The imaging element 37 detects the visible light V1 that is reflected by the street of the wafer 20 and transmitted through the converging part 34, the dichroic mirror 33, and the half mirror 36. In the laser processing apparatus 1, the control part 5 moves the converging part 34 in the Z direction based on the detection result by the imaging element 37, for example, so that the converging point of the laser light L is located on the street of the wafer 20.

The image capturing part 4 acquires image data of the street of the wafer 20 supported by the support part 2. The image capturing part 4 includes a light source 41, a half mirror 42, a converging part 43, and an imaging element 44. The light source 41 emits visible light V2. The half mirror 42 reflects the visible light V2 emitted from the light source 41 and enters the visible light V2 into the converging part 43. The converging part 43 converges the visible light V2 reflected by the half mirror 42 on the street of the wafer 20 supported by the support part 2. The imaging element 44 detects the visible light V2 that is reflected by the street of the wafer 20 and transmitted through the converging part 43 and the half mirror 42.

The control part 5 controls the operation of each part in the laser processing apparatus 1. The control part 5 includes a processing unit 51, a storage unit 52, and an input reception unit 53. The processing unit 51 is a computer device including a processor, a memory, a storage, a communication device, and the like. In the processing unit 51, the processor executes software (program) read into the memory or the like, and controls reading and writing of data in the memory and the storage, and communication by a communication device. The storage unit 52 is, for example, a hard disk or the like, and stores various types of data. The input reception unit 53 is an interface unit that receives inputs of various types of data from an operator. As an example, the input reception unit 53 is at least one of a keyboard, a mouse, and a graphical user interface (GUI).

[Configuration of Wafer]

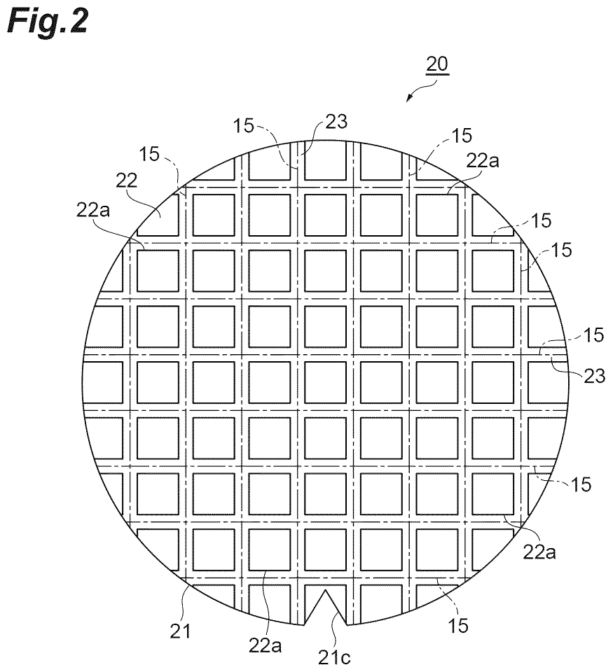

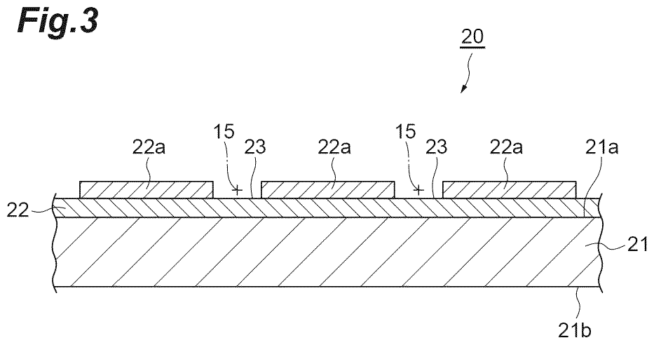

As illustrated in FIGS. 2 and 3, the wafer 20 includes a semiconductor substrate 21 and a functional element layer 22. The semiconductor substrate 21 has a front surface 21a and a back surface 21b. The semiconductor substrate 21 is, for example, a silicon substrate. A notch 21c indicating a crystal orientation is provided in the semiconductor substrate 21. The semiconductor substrate 21 may be provided with an orientation flat instead of the notch 21c. The functional element layer 22 is formed on the front surface 21a of the semiconductor substrate 21. The functional element layer 22 includes a plurality of functional elements 22a. The plurality of functional elements 22a are two-dimensionally disposed along the front surface 21a of the semiconductor substrate 21. Each of the functional elements 22a is, for example, a light receiving element such as a photodiode, a light emitting element such as a laser diode, a circuit element such as a memory, or the like. Each of the functional elements 22a may be configured three-dimensionally by stacking a plurality of layers.

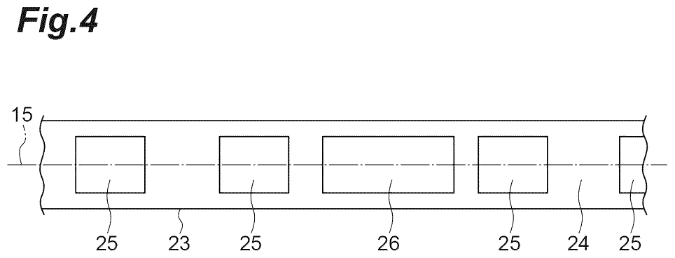

A plurality of streets 23 are formed on the wafer 20. The plurality of streets 23 are regions exposed to the outside between the adjacent functional elements 22a. That is, the plurality of functional elements 22a are disposed to be adjacent to each other via the street 23. As an example, the plurality of streets 23 extend in a lattice shape so as to pass between the adjacent functional elements 22a with respect to the plurality of functional elements 22a arranged in a matrix. As illustrated in FIG. 4, an insulating film 24 and a plurality of metal structures 25 and 26 are formed on the surface layer of the street 23. The insulating film 24 is, for example, a Low-k film. Each of the metal structures 25 and 26 is, for example, a metal pad. The metal structure 25 and the metal structure 26 are different from each other in at least one of a thickness, an area, and a material, for example.

As illustrated in FIGS. 2 and 3, the wafer 20 is scheduled to be cut along each of a plurality of lines 15 for each functional element 22a (that is, scheduled to be chipped for each functional element 22a). Each line 15 passes through each street 23 when viewed from a thickness direction of the wafer 20. As an example, each line 15 extends to pass through the center of each street 23 when viewed from the thickness direction of the wafer 20. Each line 15 is a virtual line set on the wafer 20 by the laser processing apparatus 1. Each line 15 may be a line actually drawn on the wafer 20.

[Operation of Laser Processing Device and Laser Processing Method]

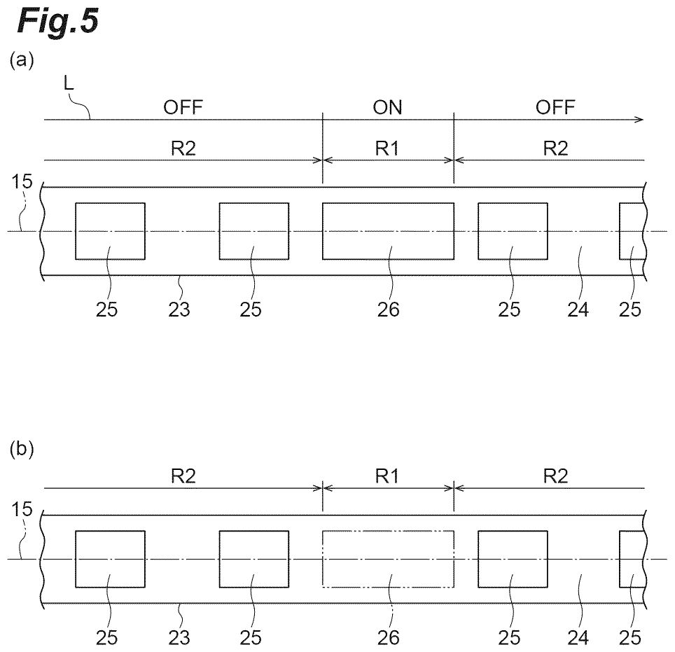

The laser processing apparatus 1 performs grooving processing of removing the surface layer of each street 23 by irradiating each street 23 with laser light L. Specifically, the control part 5 controls the irradiation part 3 such that each street 23 of the wafer 20 supported by the support part 2 is irradiated with the laser light L, and the control part 5 controls the support part 2 such that the laser light L relatively moves along each street 23. At this time, as illustrated in (a) of FIG. 5, the control part 5 controls the irradiation part 3 such that the output of the laser light L is turned ON when the laser light L relatively moves on the first region R1, and the output of the laser light L is turned OFF when the laser light L relatively moves on the second region R2. In the wafer 20, the first region R1 is a region corresponding to the metal structure 26 in each street 23, and the second region R2 is a region other than the first region R1 in each street 23.

As a result, as illustrated in (b) of FIG. 5, the surface layer (that is, the metal structure 26) of the street 23 is removed in the first region R1 of each street 23, and the surface layer (that is, the insulating film 24 and the metal structure 25) of the street 23 is left in the second region R2 of each street 23. The phase that “the output of the laser light L is turned OFF when the laser light L relatively moves on the second region R2” strictly means that “if the output of the laser light L is not turned OFF, the output of the laser light L is turned OFF when a laser light emitting part (in the laser processing apparatus 1, the converging part 34) of the irradiation part 3 relatively moves with respect to the wafer 20 such that the laser light L relatively moves on the second region R2”.

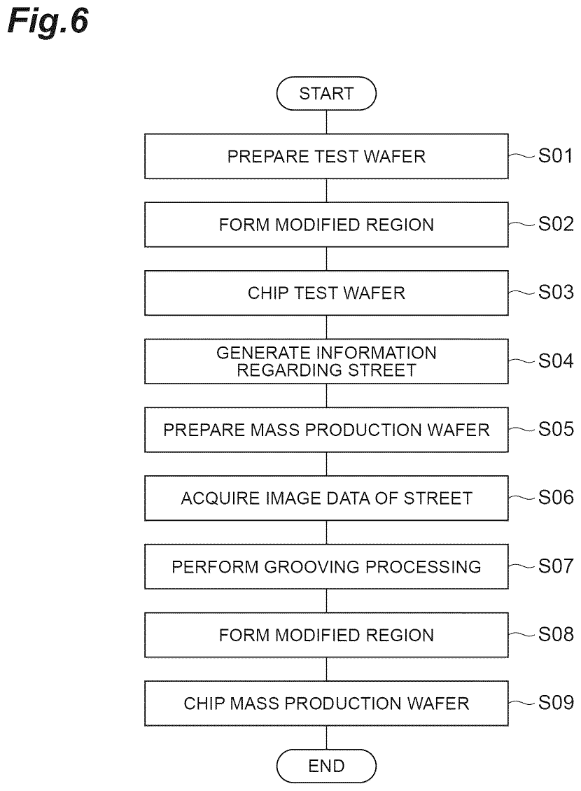

A laser processing method using the laser processing apparatus 1 will be described with reference to the flowchart of FIG. 6. First, a test wafer is prepared (S01 illustrated in FIG. 6). The test wafer has the same structure as the wafer 20 described above. That is, the wafer 20 described above can be used as the test wafer. When distinguishment is required in the following description, the above-described wafer 20 is referred to as a “mass production wafer 20”, and the test wafer is referred to as a “test wafer 20A”.

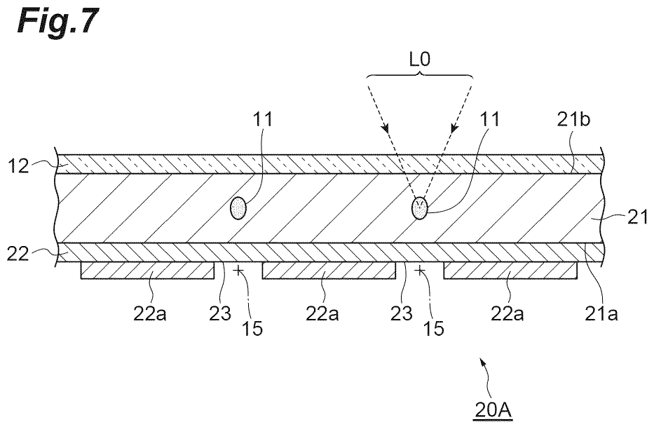

Then, as illustrated in FIG. 7, in the laser processing apparatus (not illustrated), a modified region 11 is formed in the test wafer 20A along each line 15 by irradiating the test wafer 20A with laser light L0 along each line 15 (S02 illustrated in FIG. 6). The condition for forming the modified region 11 in the test wafer 20A is the same as the condition for forming the modified region 11 in the mass production wafer 20 (details will be described later).

As an example, in a state where an expanded film 12 is adhered to the back surface 21b of the semiconductor substrate 21, the converging point of the laser light L0 is aligned in the semiconductor substrate 21 via the expanded film 12, and the test wafer 20A is irradiated with the laser light L0. The laser light L0 has transparency with respect to the expanded film 12 and the semiconductor substrate 21. When the laser light L0 is converged in the semiconductor substrate 21, the laser light L0 is absorbed in a portion corresponding to the converging point of the laser light L0, and the modified region 11 is formed in the semiconductor substrate 21. The modified region 11 is a region in which the density, the refractive index, the mechanical strength, and other physical properties are different from those of the surrounding non-modified region. Examples of the modified region 11 include a melting treatment region, a crack region, a dielectric breakdown region, and a refractive index change region. The modified region 11 has a characteristic that fractures easily extend from the modified region 11 to the incident side of the laser light L0 and the opposite side of the incident side.

Then, in an expanding device, the expanded film 12 is expanded, so that a fracture extends in the thickness direction of the test wafer 20A from the modified region 11 formed in the semiconductor substrate 21 along each line 15, and the test wafer 20A is chipped for each functional element 22a (S03 illustrated in FIG. 6).

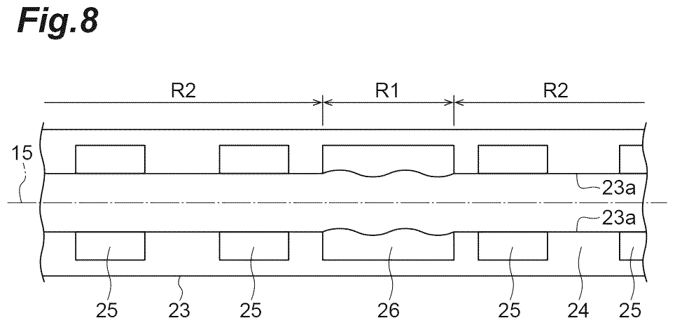

Then, for example, in an image capturing device included in the expanding device, for a plurality of chips obtained from the test wafer 20A, image data of each street 23 is acquired. In addition, in an image processing device, information regarding the street 23 is generated based on the image data of each street 23 (S04 illustrated in FIG. 6). When an image of each street 23 includes an image illustrated in FIG. 8, the information regarding the street 23 includes information indicating that, “when the modified region 11 is formed in the wafer 20 along the line 15 passing through the street 23, a fracture extending from the modified region 11 does not reach the street 23 along the line 15 in the first region R1, and reaches the street 23 along the line 15 in the second region R2”. As described above, the information regarding the street 23 is acquired by using the test wafer 20A (third step). The information regarding the street 23 is stored by the storage unit 52 of the control part 5 in the laser processing apparatus 1.

Here, the phase that “the fracture extending from the modified region 11 reaches the street 23 along the line 15 passing through the street 23” means that “the fracture extending from the modified region 11 reaches the street 23, and the meandering of each of both edges 23a of the cut street 23 falls within a predetermined width (a predetermined width in a direction perpendicular to the line 15)”. In addition, the phase that “the fracture extending from the modified region 11 does not reach the street 23 along the line 15 passing through the street 23” means that “the meandering of each of both edges 23a of the cut street 23 exceeds a predetermined width even though the fracture extending from the modified region 11 does not reach the street 23 or the fracture extending from the modified region 11 reaches the street 23”. The predetermined width is, for example, a value of 5 μm or more and 20 μm or less, and is appropriately set.

Then, the mass production wafer 20 is prepared (S05 illustrated in FIG. 6) (first step). In the laser processing apparatus 1, image data of each street 23 of the mass production wafer 20 is acquired by the image capturing part 4, in a state where the mass production wafer 20 is supported by the support part 2 (S06 illustrated in FIG. 6). The image data is stored by the storage unit 52 of the control part 5 in the laser processing apparatus 1. Then, in the laser processing apparatus 1, the mass production wafer 20 is subjected to grooving processing (S07 illustrated in FIG. 6) (second step).

Specifically, the control part 5 controls the irradiation part 3 such that each street 23 of the mass production wafer 20 supported by the support part 2 is irradiated with the laser light L, and the control part 5 controls the support part 2 such that the laser light L relatively moves along each street 23. At this time, the control part 5 controls the irradiation part 3 based on the image data of each street 23 acquired from the image capturing part 4 and the information regarding the street 23 acquired from the image processing device, such that the surface layer of the street 23 is removed in the first region R1 of each street 23, and the surface layer of the street 23 remains in the second region R2 of each street 23, as illustrated in (a) and (b) of FIG. 5.

In the laser processing apparatus 1, the control part 5 generates, in advance, the position information of at least one of the first region R1 and the second region R2 in each street 23 based on the image data of each street 23 acquired from the image capturing part 4 (the position information is stored by the storage unit 52 of the control part 5 in the laser processing apparatus 1). In addition, the control part 5 controls the irradiation part 3 such that the output of the laser light L is turned ON when the laser light L relatively moves on the first region R1, and the output of the laser light L is turned OFF when the laser light L relatively moves on the second region R2, as illustrated in (a) of FIG. 5.

As a result, as illustrated in (b) of FIG. 5, the surface layer (that is, the metal structure 26) of the street 23 is removed in the first region R1 of each street 23, and the surface layer (that is, the insulating film 24 and the plurality of metal structures 25) of the street 23 is left in the second region R2 of each street 23.

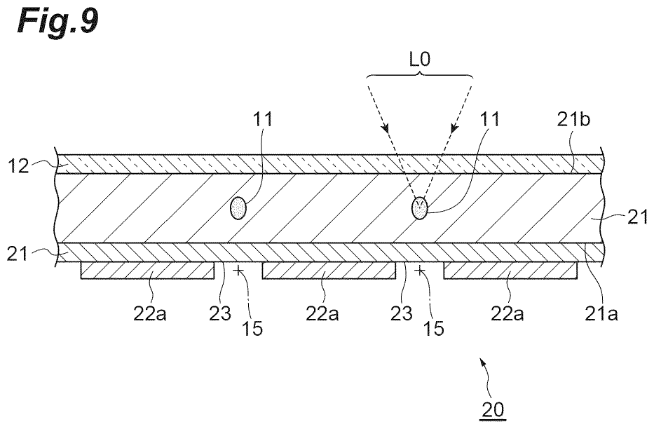

Then, as illustrated in FIG. 9, in the laser processing apparatus (not illustrated), the modified region 11 is formed in the mass production wafer 20 along each line 15 by irradiating the mass production wafer 20 with laser light L0 along each line 15 (S08 illustrated in FIG. 6) (fourth step). The condition for forming the modified region 11 in the mass production wafer 20 (for example, the number of rows and positions of the modified regions 11 formed for one line 15, irradiation conditions of the laser light L0 for forming the modified region 11 along each line 15, and the like) is used as the condition for forming the modified region 11 in the test wafer 20A.

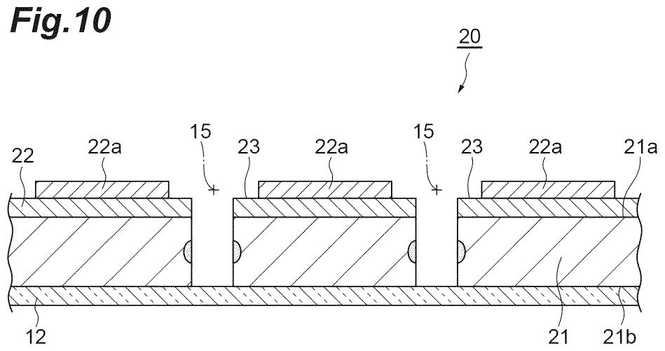

Then, as illustrated in FIG. 10, in the expanding device (not illustrated), the expanded film 12 is expanded, so that a fracture extends in the thickness direction of the mass production wafer 20 from the modified region 11 formed in the semiconductor substrate 21 along each line 15, and the mass production wafer 20 is chipped for each functional element 22a (S09 illustrated in FIG. 6).

### Actions and Effects

In the laser processing apparatus 1 and the laser processing method (laser processing method using the laser processing apparatus 1), the surface layer of the street 23 is removed in the first region R1 having an assumption “that, when the modified region 11 is formed in the wafer 20 along the line 15 passing through the street 23, the fracture extending from the modified region 11 does not reach the street 23 along the line 15”. In addition, the surface layer of the street 23 is not removed in the second region R2 having an assumption “that, when the modified region 11 is formed in the wafer 20 along the line 15 passing through the street 23, the fracture extending from the modified region 11 reaches the street 23 along the line 15”. Thus, when the wafer 20 is chipped for each functional element 22a, it is possible to cause the fracture extending from the modified region 11 to reach the street 23 along the line 15 in the first region R1 and the second region R2. In addition, it is possible to prevent an occurrence of thermal damage at least in a portion corresponding to the second region R2. Therefore, the laser processing apparatus 1 and the laser processing method using the laser processing apparatus 1 make it possible to reliably chip the wafer 20 for each functional element 22a and to suppress deterioration in chip quality.

In the laser processing apparatus 1 and the laser processing method, the control part 5 controls the support part 2 such that the laser light L relatively moves along the street 23, and the control part 5 controls the irradiation part 3 such that the output of the laser light L is turned ON when the laser light L relatively moves on the first region R1, and the output of the laser light L is turned OFF when the laser light L relatively moves on the second region R2. Thus, it is possible to reliably remove the surface layer of the street 23 in the first region R1, and to reliably leave the surface layer of the street 23 in the second region R2.

In the laser processing apparatus 1 and the laser processing method, the image capturing part 4 acquires the image data of the street 23, and the control part 5 controls the irradiation part 3 based on the image data of the street 23 and the information regarding the street 23 such that the surface layer of the street 23 is removed in the first region R1 and the surface layer of the street 23 remains in the second region R2. Thus, it is possible to reliably perform the irradiation with the laser light L in which the surface layer of the street 23 is removed in the first region R1 and the surface layer of the street 23 is left in the second region R2.

In the laser processing method, the test wafer 20A is used to acquire the information regarding the street 23. Thus, it is possible to easily and accurately acquire the information regarding the street 23.

In the laser processing method, the mass production wafer 20 is subjected to the grooving processing, and then, the modified region 11 is formed in the mass production wafer 20 along each line 15. Thus, it is possible to chip the mass production wafer 20 for each functional element 22a by causing the fracture extending from the modified region 11 to reach the street 23 along the line 15.

### Modification Examples

The present disclosure is not limited to the above embodiment. For example, in the information regarding the street 23, information regarding the first region R1 having an assumption that “the fracture extending from the modified region 11 does not reach the street 23 along the line 15 when the modified region 11 is formed in the wafer 20 along the line 15 passing through the street 23” may be subdivided into pieces of information regarding a plurality of types of the first regions R1. In this case, the irradiation condition of the laser light L may be changed for each type of the first region R1.

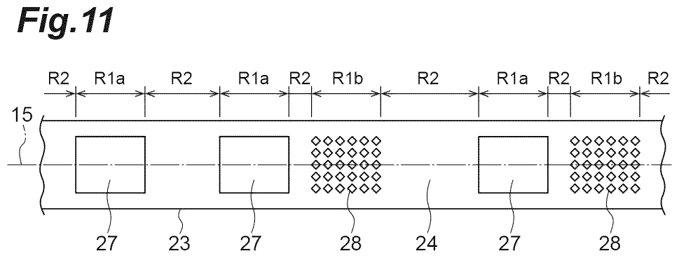

As an example, as illustrated in FIG. 11, in a case where the insulating film 24 and a plurality of metal structures 27 and 28 are formed on the surface layer of the street 23, when a first region R1a is set to a region corresponding to the metal structure 27, a first region R1b is set to a region corresponding to the metal structure 28, and the second region R2 is set to a region other than the metal structures 27 and 28, the irradiation condition of the laser light L may be changed between the first region R1a and the first region Rib, as follows. Each metal structure 27 is, for example, a metal pad, and each metal structure 28 is, for example, a metal pile.

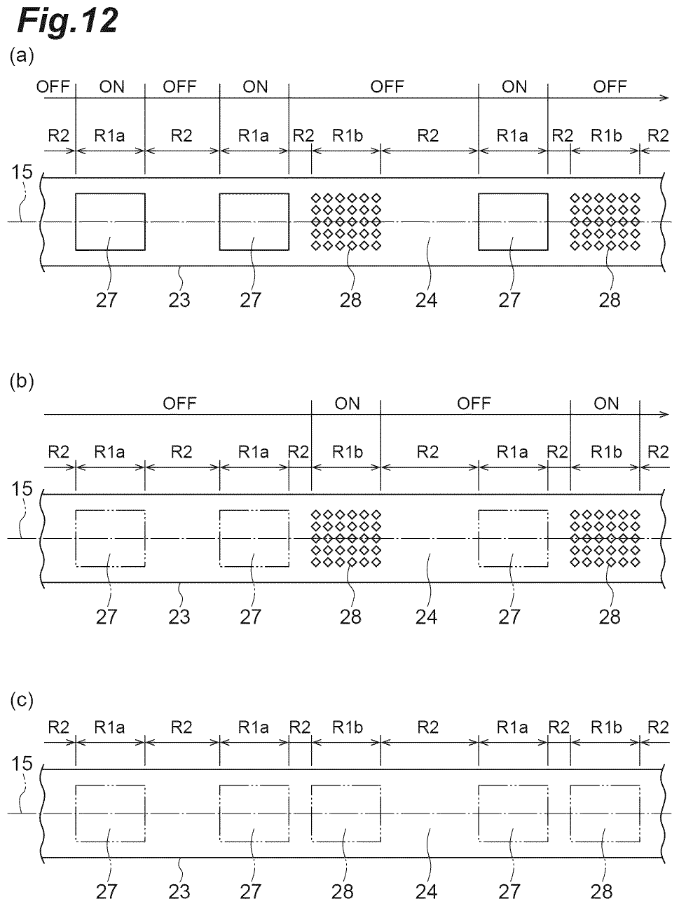

First, as illustrated in (a) of FIG. 12, the control part 5 controls the irradiation part 3 such that the output of the laser light L is turned ON at a first output when the laser light L relatively moves on the first region R1a, and the output of the laser light L is turned OFF when the laser light L relatively moves on the first region R1b and the second region R2. Then, as illustrated in (b) of FIG. 12, the control part 5 controls the irradiation part 3 such that the output of the laser light L is turned ON at a second output (for example, an output lower than the first output) when the laser light L relatively moves on the first region R1b, and the output of the laser light L is turned OFF when the laser light L relatively moves on the first region R1a and the second region R2.

As a result, as illustrated in (c) of FIG. 12, the surface layer (that is, the metal structures 27 and 28) of the street 23 is removed in the first regions R1a and R1b of each street 23, and the surface layer (that is, the insulating film 24) of the street 23 is left in the second region R2 of each street 23. When the laser light L relatively moves along the street 23, for example, the phase of the laser light L may be modulated by the spatial light modulator included in the shaping optical system 32, so as to differ between the first region R1a and the first region R1b. In this case, the surface layer (that is, the metal structures 27 and 28) of the street 23 can be removed in the first regions R1a and R1b of the street 23 by one scanning of the laser light L on the street 23.

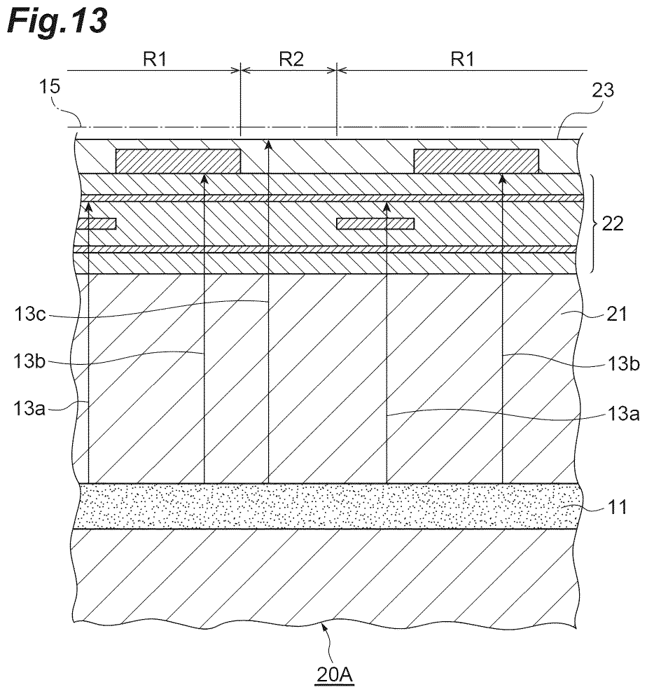

Furthermore, the information regarding the street 23 may include position information of the tip of the fracture that does not reach the first region R1. As an example, as illustrated in FIG. 13, in a case where the modified region 11 is formed in the test wafer 20A along the line 15 passing through the street 23, when fractures 13a and 13b extending from the modified region 11 do not reach the street 23 along the line 15 in the first region R1, and a fracture 13c extending from the modified region 11 reaches the street 23 along the line 15 in the second region R2, the information regarding the street 23 may include the position information of the tip (tip on the street 23 side) of each of the fractures 13a and 13b. According to this configuration, it is possible to irradiate the first region R1 with the laser light L so that the fractures 13a and 13b extending from the modified region 11 reliably reaches the street 23 along the line 15 in the first region R1 in which the surface layer of the street 23 is removed. The tip of each of the fractures 13a and 13b may be detected by an infrared image capturing part. In this case, the laser processing apparatus 1 may include the infrared image capturing part instead of the image capturing part 4, or may include the infrared image capturing part together with the image capturing part 4. The infrared image capturing part is a camera that emits infrared light to an object and acquires an image of the object by the infrared light as image data. As the infrared image capturing part, for example, an InGaAs camera can be used. As described above, in the laser processing apparatus 1 and the laser processing method, information for controlling the irradiation condition (laser ON/OFF control, laser power) of the laser light L in each region of the street 23 is created by using the image obtained by capturing an image of at least the surface layer of the street 23 after cutting and the perspective image using infrared rays. Then, the grooving processing is controlled based on the created information.

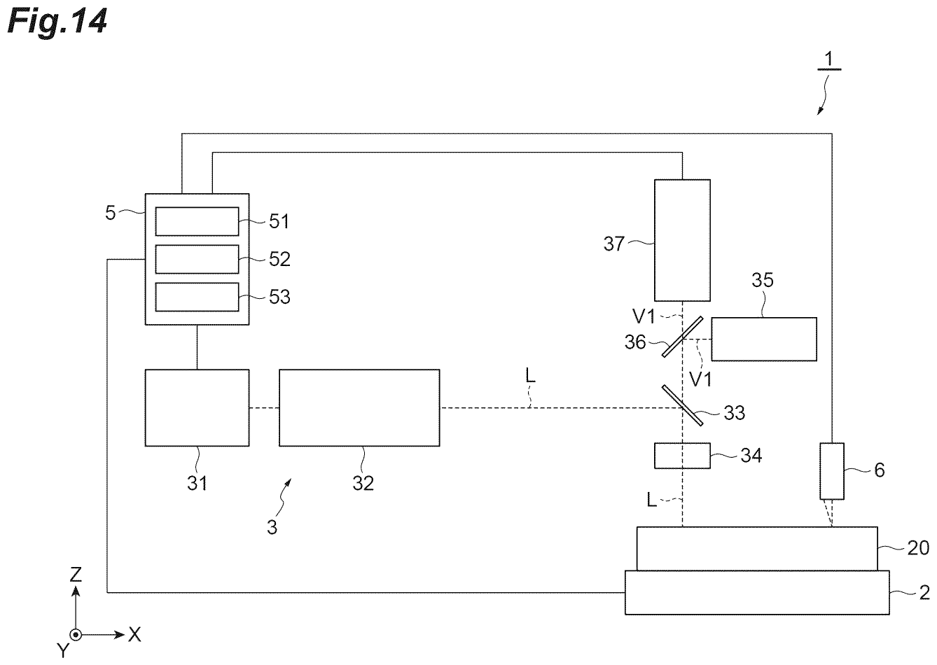

As illustrated in FIG. 14, the laser processing apparatus 1 may further include a distance measuring part 6 that acquires height data of the street 23. In this case, the control part 5 may control the irradiation part 3 based on the height data of the street 23 and the information regarding the street 23 such that the surface layer of the street 23 is removed in the first region R1 and the surface layer of the street 23 remains in the second region R2. The distance measuring part 6 is a sensor that acquires height data of the street 23 by emitting distance measurement light (for example, laser light) to the street 23 and detecting the distance measurement light reflected by street 23. As the distance measuring part 6, for example, a laser displacement meter of as a triangulation type, a spectral interference type, a multi-color confocal type, a monochromatic confocal type, or the like can be used.

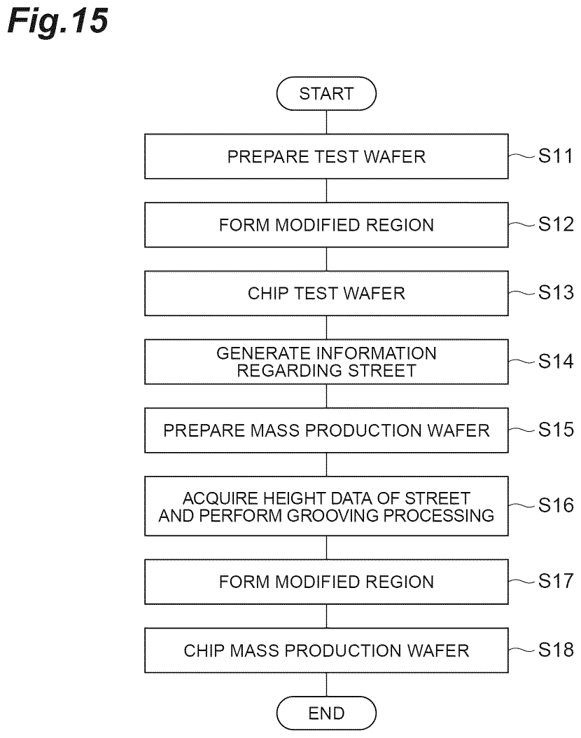

The laser processing apparatus 1 may include the distance measuring part 6 instead of the image capturing part 4, or may include the distance measuring part 6 together with at least one of the image capturing part 4 and the above-described infrared image capturing part. A laser processing method using the laser processing apparatus 1 illustrated in FIG. 14 will be described with reference to the flowchart of FIG. 15.

First, a test wafer 20A is prepared (S11 illustrated in FIG. 15). Then, in the laser processing apparatus, a modified region 11 is formed in the test wafer 20A along each line 15 by irradiating the test wafer 20A with laser light L0 along each line 15 (S12 illustrated in FIG. 15). The condition for forming the modified region 11 in the test wafer 20A is the same as the condition for forming the modified region 11 in the mass production wafer 20. Then, in an expanding device, the expanded film 12 is expanded, so that a fracture extends in the thickness direction of the test wafer 20A from the modified region 11 formed in the semiconductor substrate 21 along each line 15, and the test wafer 20A is chipped for each functional element 22a (S13 illustrated in FIG. 15).

Then, for example, in an image capturing device included in the expanding device, for a plurality of chips obtained from the test wafer 20A, image data of each street 23 is acquired. In addition, in an image processing device, information regarding the street 23 is generated based on the image data of each street 23 (S14 illustrated in FIG. 15). As described above, the information regarding the street 23 is acquired by using the test wafer 20A (third step). The information regarding the street 23 is stored by the storage unit 52 of the control part 5 in the laser processing apparatus 1 illustrated in FIG. 14.

Then, the mass production wafer 20 is prepared (S15 illustrated in FIG. 15) (first step). Then, in the laser processing apparatus 1 illustrated in FIG. 14, while the height data of the street 23 is acquired by the distance measuring part 6, the grooving processing is performed on the mass production wafer 20 (S16 illustrated in FIG. 15) (second step).

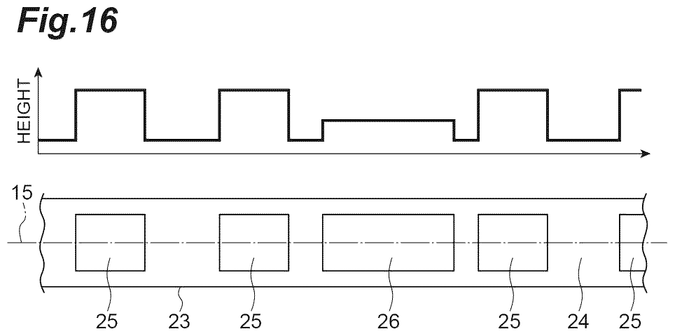

Specifically, the control part 5 controls the irradiation part 3 such that each street 23 of the mass production wafer 20 supported by the support part 2 is irradiated with the laser light L, and the control part 5 controls the support part 2 such that the laser light L relatively moves along each street 23. At this time, in the street 23, the distance measuring part 6 precedes the converging part 34, thereby the height data of the street 23 is acquired as illustrated in FIG. 16. The control part 5 controls the irradiation part 3 based on the height data of the street 23 acquired from the distance measuring part 6 and the information regarding the street 23 acquired from the image processing device, such that the surface layer of the street 23 is removed in the first region R1 of each street 23, and the surface layer of the street 23 remains in the second region R2 of each street 23.

As illustrated in FIG. 16, the height of the insulating film 24, the height of the metal structure 25, and the height of the metal structure 26 are different from each other. Therefore, the control part 5 can acquire position information of at least one of the first region R1 and the second region R2 in the street 23 in advance based on the height data of the street 23 acquired from the distance measuring part 6. In the laser processing apparatus 1 illustrated in FIG. 14, the control part 5 controls the irradiation part 3 based on the position information of at least one of the first region R1 and the second region R2 in the street 23 such that the output of the laser light L is turned ON when the converging part 34 (that is, the laser light L) relatively moves on the first region R1, and the output of the laser light L is turned OFF when the converging part 34 relatively moves on the second region R2. As a result, the surface layer of the street 23 is removed in the first region R1 of each street 23, and the surface layer of the street 23 is left in the second region R2 of each street 23.

Then, in the laser processing apparatus, the modified region 11 is formed in the mass production wafer 20 along each line 15 by irradiating the mass production wafer 20 with laser light L0 along each line 15 (S17 illustrated in FIG. 15) (fourth step). The condition for forming the modified region 11 in the mass production wafer 20 is used as the condition for forming the modified region 11 in the test wafer 20A. Then, in the expanding device, the expanded film 12 is expanded, so that a fracture extends in the thickness direction of the mass production wafer 20 from the modified region 11 formed in the semiconductor substrate 21 along each line 15, and the mass production wafer 20 is chipped for each functional element 22a (S18 illustrated in FIG. 15).

As described above, in the laser processing apparatus 1 illustrated in FIG. 14, the distance measuring part 6 acquires the height data of the street 23, and the control part 5 controls the irradiation part 3 based on the height data of the street 23 and the information regarding the street 23 such that the surface layer of the street 23 is removed in the first region R1 and the surface layer of the street 23 remains in the second region R2. Thus, it is possible to reliably perform the irradiation with the laser light L in which the surface layer of the street 23 is removed in the first region R1 and the surface layer of the street 23 is left in the second region R2.

In addition, the control part 5 may control the irradiation part 3 based on the information regarding the street 23 and at least one of the image data of the street 23, the height data of the street 23, and the position information of the tip of the fracture that does not reach the first region R1, such that the surface layer of the street 23 is removed in the first region R1 of each street 23, and the surface layer of the street 23 remains in the second region R2 of each street 23. Alternatively, the control part 5 may control the irradiation part 3 based on the information regarding the street 23 without using the image data of the street 23, the height data of the street 23, and the position information of the tip of the fracture that does not reach the first region R1, such that the surface layer of the street 23 is removed in the first region R1 of each street 23, and the surface layer of the street 23 remains in the second region R2 of each street 23. For example, when design data or the like of the wafer 20 is input to the control part 5 and the control part 5 acquires, in advance, the position information of at least one of the first region R1 and the second region R2 in each street 23, the control part 5 does not need to use the image data of the street 23 and the height data of the street 23.

Furthermore, the control part 5 may control the irradiation part 3 based on the information regarding the street 23 such that the street 23 is irradiated with the laser light L under a first irradiation condition (irradiation condition under which the surface layer of the street 23 is removed) when the laser light L relatively moves on the first region R1, and the street 23 is irradiated with the laser light L under a second irradiation condition (irradiation condition under which the surface layer of the street 23 remains) when the laser light L relatively moves on the second region R2. In addition, the control part 5 may remove the surface layer of the street 23 in the first region R1 of the street 23 by scanning the street 23 with the laser light L a plurality of times. Furthermore, the control part 5 may control only the support part 2, may control only the irradiation part 3, or may control both the support part 2 and the irradiation part 3, such that the laser light L relatively moves along each street 23.

In the laser processing method, the modified region 11 may be formed in the mass production wafer 20 along each line 15 after the grooving processing is performed on the mass production wafer 20, or the grooving processing may be performed on the mass production wafer 20 after the modified region 11 is formed in the mass production wafer 20 along each line 15.

### REFERENCE SIGNS LIST

1 laser processing apparatus
2 support part
3 irradiation part
4 image capturing part
5 control part
6 distance measuring part
11 modified region
15 line
20 wafer
20A test wafer
22a functional element
23 street
L laser light
R1, R1a, R1b first region
R2 second region

1. A laser processing apparatus comprising:
a support part configured to support a wafer including a plurality of functional elements disposed to be adjacent to each other via a street;
an irradiation part configured to irradiate the street with laser light; and
a control part configured to control the irradiation part based on information regarding the street such that a surface layer of the street is removed in a first region of the street and the surface layer remains in a second region of the street, wherein
the information regarding the street includes information indicating that, when a modified region is formed in the wafer along a line passing through the street, a fracture extending from the modified region does not reach the street along the line in the first region, and reaches the street along the line in the second region.

2. The laser processing apparatus according to claim 1, wherein
the control part controls at least one of the support part and the irradiation part such that the laser light relatively moves along the street, and
the control part controls the irradiation part such that an output of the laser light is turned ON when the laser light relatively moves on the first region, and the output of the laser light is turned OFF when the laser light relatively moves on the second region.

3. The laser processing apparatus according to claim 1, further comprising:
an image capturing part configured to acquire image data of the street, wherein
the control part controls the irradiation part based on the image data and the information regarding the street such that the surface layer is removed in the first region and the surface layer remains in the second region.

4. The laser processing apparatus according to claim 1, further comprising:
a distance measuring part configured to acquire height data of the street, wherein
the control part controls the irradiation part based on the height data and the information regarding the street such that the surface layer is removed in the first region and the surface layer remains in the second region.

5. The laser processing apparatus according to claim 1, wherein
the information regarding the street includes position information of a tip of the fracture that does not reach the first region.

6. A laser processing method comprising:
a first step of preparing a wafer including a plurality of functional elements disposed to be adjacent to each other via a street; and
a second step of, after the first step, irradiating the street with laser light based on information regarding the street such that a surface layer of the street is removed in a first region of the street and the surface layer remains in a second region of the street, wherein
the information regarding the street includes information indicating that, when a modified region is formed in the wafer along a line passing through the street, a fracture extending from the modified region does not reach the street along the line in the first region, and reaches the street along the line in the second region.

7. The laser processing method according to claim 6, further comprising:
a third step of acquiring the information regarding the street by using a test wafer, before the first step.

8. The laser processing method according to claim 6, further comprising:
a fourth step of forming the modified region in the wafer along the line, after the first step.
